(19) United States
(12) Patent Application Publication
(10) Pub. No.: US 2026/0106257 A1
(43) Pub. Date: Apr. 16, 2026

(54) PROACTIVE TEMPERATURE MANAGEMENT STRATEGY FOR VEHICLE BATTERY SYSTEMS

(71) Applicant: FCA US LLC, Auburn Hills, MI (US)

(72) Inventors: Shuo Zhao, Shanghai (CN); Zhong Zheng, Shanghai (CN); Zhenquan Chen, Shanghai (CN); Yang Xu, Shanghai (CN)

(21) Appl. No.: 18/917,301

(22) Filed: Oct. 16, 2024

(51) Int. Cl. H01M 10/63; G01R 31/387; H01M 10/48; H01M 10/613; H01M 10/625; H01M 10/651; H01M 10/6563; H01M 10/6568

(52) U.S. Cl. CPC H01M 10/63; G01R 31/387; H01M 10/486; H01M 10/613; H01M 10/625; H01M 10/651; H01M 10/6563; H01M 10/6568

(57) ABSTRACT

A proactive temperature management technique for a battery system of an electrified vehicle includes estimating a temperature of the battery system based on measured inlet and outlet temperatures of a fluid in the cooling system at respective inlet and output points of the cooling system relative to the battery system, detecting a proactive temperature management condition when a measured current flowing through the battery system exceeds one or more current thresholds, in response to detecting the proactive temperature management condition, controlling the cooling system to increase a flow of the fluid therethrough to proactively cool the battery system to a target temperature, after the proactive temperature management condition has expired, estimating a state of charge (SOC) of the battery system based on the estimated temperature of the battery system, and controlling the battery system based on the estimated SOC of the battery system.

### FIELD

The present application generally relates to electrified vehicles and, more particularly, to a proactive temperature management strategy for electrified vehicle battery systems.

### BACKGROUND

An electrified vehicle includes a high voltage battery pack or system comprising a plurality of battery cells (e.g., lithium-ion type cells) connected together to collectively output a voltage. These high voltage battery systems are capable of generating large amounts of heat during operation due to the high currents flowing therethrough. Thus, these battery systems often include a cooling system that circulates a fluid (air, liquid coolant, etc.) through the battery system. In this configuration, temperature sensors are typically positioned along the cooling system at an inlet and an outlet of the battery system. Conventional thermal management techniques enable the cooling system when the inlet/outlet temperature sensors indicate a temperature change that exceeds a temperature threshold. However, these inlet/outlet temperature sensors may not accurately reflect the actual internal temperature of the battery system. That is, even if the outlet temperature does not exceed a threshold value, the internal temperature of the battery system may have exceeded the threshold value. Accordingly, while such conventional battery thermal management systems do work for their intended purpose, there exists an opportunity for improvement in the relevant art.

### SUMMARY

According to one example aspect of the invention, a proactive temperature management system for a battery system of an electrified vehicle is presented. IN one exemplary implementation, the proactive temperature management system comprises a set of sensors configured to measure (i) a current flowing through the battery system and (ii) an inlet temperature and an outlet temperature of a fluid in the cooling system at respective inlet and output points of the cooling system relative to the battery system and a control system configured to estimate a temperature of the battery system based on the measured inlet and outlet temperatures, detect a proactive temperature management condition when the measured current exceeds one or more current thresholds, in response to detecting the proactive temperature management condition, control the cooling system to increase a flow of the fluid therethrough to proactively cool the battery system to a target temperature, after the proactive temperature management condition has expired, estimate a state of charge (SOC) of the battery system based on the estimated temperature of the battery system, and control the battery system based on the estimated SOC of the battery system.

In some implementations, the proactive cooling of the battery system increases an accuracy of the estimated SOC of the battery system and thereby improves discharge performance of the battery system. In some implementations, the control system is configured to detect the proactive temperature management condition when (i) a magnitude of the measured current exceeds a calibratable current magnitude threshold and (ii) a rate of change of the measured current exceeds a calibratable current rate of change threshold.

In some implementations, the proactive temperature management condition expires when a difference between the measured outlet temperature and the target temperature for the battery system falls below one or more respective thresholds. In some implementations, the proactive temperature management condition expires when (i) an absolute value of the difference between the measured outlet temperature and the target temperature is less than a calibratable difference threshold and (ii) a rate of change of the difference between the measured outlet temperature and the target temperature is less than a calibratable temperature rate of change threshold.

In some implementations, the control of the cooling system to increase the flow of the fluid therethrough comprises controlling a flow control device of the cooling system. In some implementations, the controlling of the flow control device of the cooling system includes selecting and commanding one of at least two different flow rates for the flow control device, wherein each of the at least two different flow rates is greater than zero. In some implementations, the selecting of the one of the at least two different flow rates is performed based on a difference between the estimated temperature of the battery system and a target temperature for the battery system.

In some implementations, the fluid is a liquid coolant and the flow control device includes one or more pumps configured to control the flow of the liquid coolant therethrough. In some implementations, the fluid is an air and the flow control device includes one or more fans configured to control the flow of the air therethrough.

According to another example aspect of the invention, a proactive temperature management method for a battery system of an electrified vehicle is presented. In one exemplary implementation, the proactive temperature management method comprises providing a set of sensors configured to measure (i) a current flowing through the battery system and (ii) an inlet temperature and an outlet temperature of a fluid in the cooling system at respective inlet and output points of the cooling system relative to the battery system, estimating, by a control system of the electrified vehicle, a temperature of the battery system based on the measured inlet and outlet temperatures, detecting, by the control system, a proactive temperature management condition when the measured current exceeds one or more current thresholds, in response to detecting the proactive temperature management condition, controlling, by the control system, the cooling system to increase a flow of the fluid therethrough to proactively cool the battery system to a target temperature, after the proactive temperature management condition has expired, estimating, by the control system, an SOC of the battery system based on the estimated temperature of the battery system, and controlling, by the control system, the battery system based on the estimated SOC of the battery system.

In some implementations, the proactive cooling of the battery system increases an accuracy of the estimated SOC of the battery system and thereby improves discharge performance of the battery system. In some implementations, the control system is configured to detect the proactive temperature management condition when (i) a magnitude of the measured current exceeds a calibratable current magnitude threshold and (ii) a rate of change of the measured current exceeds a calibratable current rate of change threshold.

In some implementations, the proactive temperature management condition expires when a difference between the measured outlet temperature and the target temperature for the battery system falls below one or more respective thresholds. In some implementations, the proactive temperature management condition expires when (i) an absolute value of the difference between the measured outlet temperature and the target temperature is less than a calibratable difference threshold and (ii) a rate of change of the difference between the measured outlet temperature and the target temperature is less than a calibratable temperature rate of change threshold.

In some implementations, the control of the cooling system to increase the flow of the fluid therethrough comprises controlling a flow control device of the cooling system. In some implementations, the controlling of the flow control device of the cooling system includes selecting and commanding one of at least two different flow rates for the flow control device, wherein each of the at least two different flow rates is greater than zero. In some implementations, the selecting of the one of the at least two different flow rates is performed based on a difference between the estimated temperature of the battery system and a target temperature for the battery system.

In some implementations, the fluid is a liquid coolant and the flow control device includes one or more pumps configured to control the flow of the liquid coolant therethrough. In some implementations, the fluid is an air and the flow control device includes one or more fans configured to control the flow of the air therethrough.

Further areas of applicability of the teachings of the present application will become apparent from the detailed description, claims and the drawings provided hereinafter, wherein like reference numerals refer to like features throughout the several views of the drawings. It should be understood that the detailed description, including disclosed embodiments and drawings referenced therein, are merely exemplary in nature intended for purposes of illustration only and are not intended to limit the scope of the present disclosure, its application or uses. Thus, variations that do not depart from the gist of the present application are intended to be within the scope of the present application.

### BRIEF DESCRIPTION OF THE DRAWINGS

FIG. 1 is a functional block diagram depicting an electrified vehicle having an example proactive temperature management system for a battery system according to the principles of the present application; and

FIG. 2 is a flow diagram depicting an example proactive temperature management method for a battery system of an electrified vehicle according to the principles of the present application.

### DESCRIPTION

As previously discussed, conventional thermal management techniques enable the cooling system when the inlet/outlet temperature sensors indicate a temperature change that exceeds a temperature threshold. However, these inlet/outlet temperature sensors may not accurately reflect the actual internal temperature of the battery system. That is, even if the outlet temperature does not exceed a threshold value, the internal temperature of the battery system may have exceeded the threshold value. For example, the temperature of the battery cells will increase quickly at high current output conditions, e.g., in response to a high power demand, such as corresponding to aggressive or intense acceleration. In this example, the cooling system would start to cool the battery system when the estimated temperature exceeds the temperature threshold. The cool-down process, however, takes a relatively long time, especially with continuous demand for high current output (e.g., air conditioning plus the aggressive/intense acceleration request). Operating in this high temperature condition could degrade the discharge performance of the battery system, including inaccurate state of charge (SOC) estimation and the battery cell/system life. Accordingly, proactive temperature management systems and methods for a battery system of an electrified vehicle are presented herein.

These techniques detect a proactive temperature management condition based on measured current flowing through the battery system. This thermal management condition can be based only on the measured current and not based on temperature(s) of the battery system as in conventional temperature management techniques. In one example embodiment, the proactive temperature management condition includes both a magnitude and a rate of change of the measured current exceeding respective calibratable thresholds. This “current spike” of the proactive thermal management condition corresponds to a substantial increase in an internal (cell) temperature of the battery system during the above-described transient operating scenarios (e.g., aggressive/intense acceleration). Once the proactive temperature management condition is detected, control of the cooling system of the battery system (i.e., increased fluid flow) is performed to proactively cool the battery system. Potential benefits of these techniques include more accurate SOC estimation of the battery system and, in return, improved performance (e.g., discharge control of the battery system).

This proactive cooling, in contrast to the conventional temperature feedback based techniques, occurs before a corresponding temperature spike is detected by the temperature sensors. The increased fluid flow through the cooling system could include, for example, the selection of one of at least two different flow rates for a flow control device (a fan, a pump, etc.) of the cooling system. The selection of the particular flow rate could be based on a difference between the measured temperature difference (i.e., inlet vs. outlet temperature) of the battery system and a target temperature for the battery system. This proactive control could occur until the target temperature is achieved or an expiration of the proactive temperature management condition. The expiration of the proactive temperature management condition could be, for example, when both an absolute value of a difference between the outlet and target temperatures and a rate of change of the outlet temperature fall below respective calibratable thresholds. Finally, the temperature of the battery system is estimated based on the inlet/outlet temperatures and the battery system SOC is then estimated based on the estimated temperature and the estimated SOC is used for improved control.

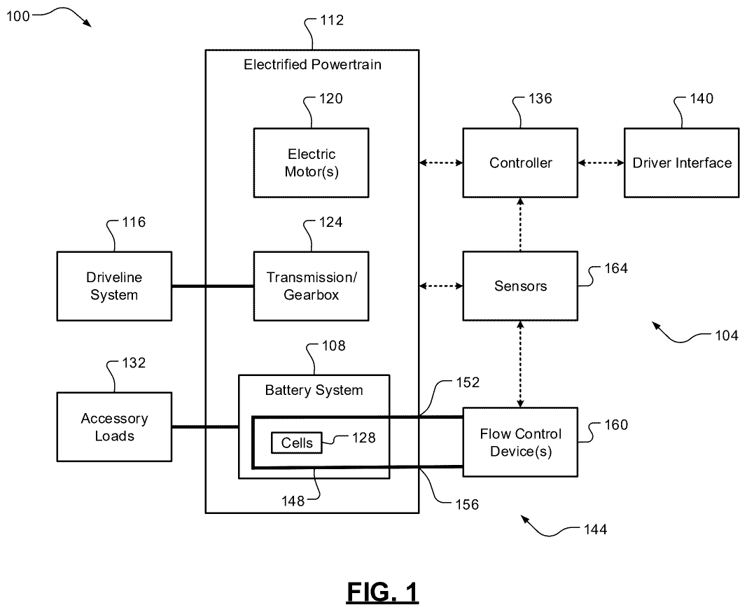

Referring now to FIG. 1, a functional block diagram depicting an electrified vehicle 100 (a battery electric vehicle, a plug-in hybrid electric vehicle, a mild hybrid electric vehicle, a range-extended electrified vehicle, etc.) having an example proactive temperature management system 104 for battery system 108 according to the principles of the present application is illustrated. The electrified vehicle 100 generally comprises an electrified powertrain 112 configured to generate and transfer drive torque to a driveline system 116 for vehicle propulsion. The electrified powertrain 112 includes one or more electric motors 120 configured to generate drive torque that is transferred to the driveline system 116 via a transmission/gearbox 124 (a gear reducer, a multi-speed automatic transmission, etc.). The electric motor(s) 120 are powered by electrical energy (current/voltage) generated by the high voltage battery pack or system 108, which comprises a plurality of battery cells 128 (e.g., lithium-ion type battery cells). The battery system 108 could also be configured to power other high voltage accessory loads 132, such as an air conditioning system. In some implementations, the electrified powertrain 108 could include other components, such as an internal combustion engine, a direct current to direct current (DC-DC) converter, and a low voltage (e.g., 12 volt) battery system.

A control system 136 controls operation of the electrified vehicle 100, which primarily includes controlling the electrified powertrain 112 to generate a desired amount of drive torque to satisfy a driver torque request. The driver torque request could be provided by a driver of the electrified vehicle 100 via a driver interface 140 (e.g., an accelerator pedal). The driver interface 140 could also be configured to receive control commands for other vehicle systems, such as the high voltage accessory loads 132. The control system 136 is also configured to control a cooling system 144 for the battery system 108, which includes a coolant path 148 that flows from an inlet point 152 through the battery system 108 (i.e., the battery cells 128) to an outlet point 156 and includes one or more flow control devices 160 (a fan, a pump, etc.) for controlling a flow of a fluid (air, a liquid coolant, etc.) through the coolant path 148. A plurality of sensors 164 are configured to measure operating parameters of the electrified vehicle 100, including, but not limited to, a current flowing through the battery system 108 (i.e., between the battery cells 128), temperatures of the fluid at the inlet point 152 and outlet points 156 of the cooling system 144, hereinafter referred to as inlet and outlet temperatures of the battery system 108 or the cooling system 144, and rates/speeds of the flow control device(s) 160. The control system 136 is also configured to perform at least a portion of the proactive temperature management techniques of the present application, which are described in greater detail below.

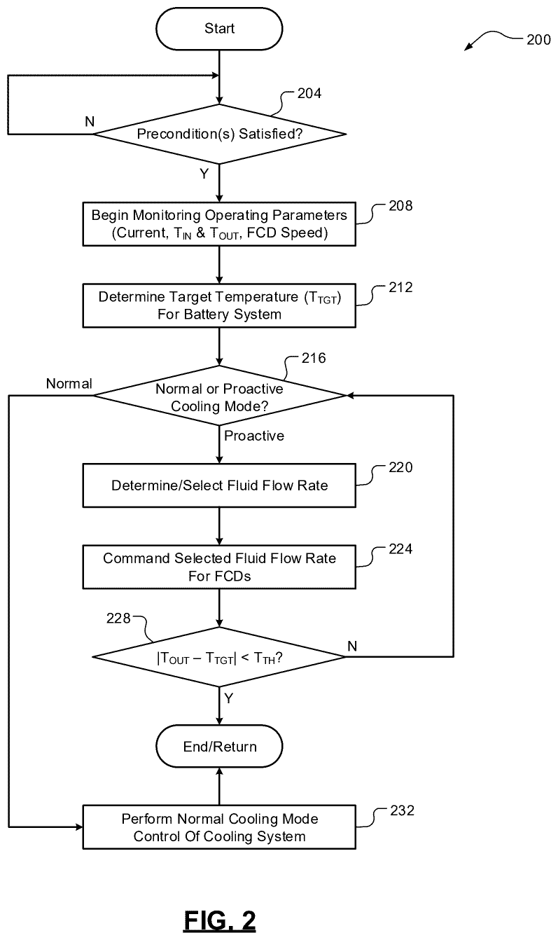

Referring now to FIG. 2 and with continued reference to FIG. 1, a flow diagram depicting an example proactive temperature management method 200 for a battery system of an electrified vehicle according to the principles of the present application is illustrated. While the electrified vehicle 100 and its components are specifically referenced for descriptive/illustrative purposes, it will be appreciated that the method 200 could be applicable to any suitably configured electrified vehicle or other non-vehicle battery system. The method 200 begins at 204. At optional 204, the control system 136 determines whether a set of one or more preconditions are satisfied. These precondition(s) could include, for example only, the electrified vehicle 100 being powered up and running and there being no malfunctions or faults present that would negatively affect or otherwise impact the operation of the techniques of the present application. When false, the method 200 ends or returns to 204. When true, the method 200 proceeds to 208. At 208, the control system 136 begins monitoring a set of operating parameters of the electrified vehicle 100, such as a current flowing through the battery system 108, the inlet and outlet temperatures (T_{IN} and T_{OUT}, respectively) of the fluid in the coolant path 148 of the cooling system at points 152 and 156, respectively, and speed(s) of the flow control device(s) (FCD) 160 (fan speed, pump speed, etc.). A temperature of the battery system 108 (T_{BATT}) could also be estimated based on the inlet and outlet temperatures T_{IN}, T_{OUT} or in another suitable manner.

At 212, the control system 136 determines a target temperature (T_{TGT}) for the battery system 108 based on these measured/monitored parameters (e.g., using a calibrated look-up table). At 216, the control system 136 determines whether a normal cooling mode or the proactive cooling mode will be utilized to cool the battery system 108. For example, the proactive cooling mode could be selected and utilized when (1) the measured current is greater than a calibrated current threshold and (2) a rate of change of the measured current is greater than a calibrated current rate of change threshold. These thresholds could be calibrated such that the proactive cooling mode will be selected/enabled during the above-described transient operations (e.g., aggressive/intense acceleration) that are likely to cause large temperature spikes at the battery system 128. When false, the method 200 proceeds to 232. When true, the method 200 proceeds to 220. At 220, the proactive cooling mode begins, which includes the control system 136 determining and selecting a fluid flow rate for the cooling system 144. In one exemplary implementation, this could include selecting between at least two different fluid flow rates (e.g., a low flow mode and a high flow mode), but it will be appreciated that the fluid flow rate could also be determined dynamically. For example, a high flow mode could be selected when a difference between the battery system temperature (T_{BATT}) and the target temperature T_{TGT} is between second and third temperature thresholds (T_{TH2}, T_{TH3}) and a lower flow mode could be selected when a difference between the battery temperature T_{BATT} and the target temperature T_{TGT} is between first and the second temperature thresholds (T_{TH1}, T_{TH2}; where T_{TH3}>T_{TH2}>T_{TH1}).

At 224, the control system 136 commands the FCD(s) 160 to operate according to the selected fluid flow rate. At 228, the control system 136 determines whether exit conditions to end the proactive cooling mode are present. These exit conditions represent temperature conditions where the proactive cooling mode is no longer needed. In one exemplary implementation, these exit conditions include (1) an absolute value of a difference between the outlet temperature T_{OUT} and the target temperature T_{TGT} is less than a temperature threshold (T_{TH}) and (2) a rate of temperature change (e.g., the difference (T_{OUT}−T_{TGT}) or the battery system temperature T_{BATT}) being less than a respective threshold. When false, the method 200 returns to 216 and the proactive cooling mode continues. When true, the method 200 proceeds to 232 where the method 200 ends (or the normal cooling mode resumes at 232). After the completion of the method 200, the proactively cooled battery system 108 can have its SOC estimated (e.g., using a Kalman-filter type estimation method) and then this more accurate SOC estimate can be used to control aspects of the electrified vehicle 100, such as discharging of the battery system 108, thereby resulting in improved performance/efficiency of the electrified vehicle 100.

It will be appreciated that the terms “controller” and “control system” as used herein refer to any suitable control device or set of multiple control devices that is/are configured to perform at least a portion of the techniques of the present application. Non-limiting examples include an application-specific integrated circuit (ASIC), one or more processors and a non-transitory memory having instructions stored thereon that, when executed by the one or more processors, cause the controller to perform a set of operations corresponding to at least a portion of the techniques of the present application. The one or more processors could be either a single processor or two or more processors operating in a parallel or distributed architecture.

It should also be understood that the mixing and matching of features, elements, methodologies and/or functions between various examples may be expressly contemplated herein so that one skilled in the art would appreciate from the present teachings that features, elements and/or functions of one example may be incorporated into another example as appropriate, unless described otherwise above.

What is claimed is:

1. A proactive temperature management system for a battery system of an electrified vehicle, the proactive temperature management system comprising:
a set of sensors configured to measure (i) a current flowing through the battery system and (ii) an inlet temperature and an outlet temperature of a fluid in a cooling system at respective inlet and output points of a coolant path of the cooling system relative to the battery system; and
a control system configured to:
estimate a temperature of the battery system based on the measured inlet and outlet temperatures;
detect a proactive temperature management condition when the measured current exceeds one or more current thresholds;
in response to detecting the proactive temperature management condition, control the cooling system to increase a flow of the fluid therethrough to proactively cool the battery system to a target temperature;
after the proactive temperature management condition has expired, estimate a state of charge (SOC) of the battery system based on the estimated temperature of the battery system; and
control the battery system based on the estimated SOC of the battery system.

2. The proactive temperature management system of claim 1, wherein the proactive cooling of the battery system increases an accuracy of the estimated SOC of the battery system and thereby improves discharge performance of the battery system.

3. The proactive temperature management system of claim 1, wherein the control system is configured to detect the proactive temperature management condition when (i) a magnitude of the measured current exceeds a calibratable current magnitude threshold and (ii) a rate of change of the measured current exceeds a calibratable current rate of change threshold.

4. The proactive temperature management system of claim 1, wherein the proactive temperature management condition expires when a difference between the measured outlet temperature and the target temperature for the battery system falls below one or more respective thresholds.

5. The proactive temperature management system of claim 4, wherein the proactive temperature management condition expires when (i) an absolute value of the difference between the measured outlet temperature and the target temperature is less than a calibratable difference threshold and (ii) a rate of change of the difference between the measured outlet temperature and the target temperature is less than a calibratable temperature rate of change threshold.

6. The proactive temperature management system of claim 1, wherein the control of the cooling system to increase the flow of the fluid therethrough comprises controlling a flow control device of the cooling system.

7. The proactive temperature management system of claim 6, wherein the controlling of the flow control device of the cooling system includes selecting and commanding one of at least two different flow rates for the flow control device, wherein each of the at least two different flow rates is greater than zero.

8. The proactive temperature management system of claim 7, wherein the selecting of the one of the at least two different flow rates is performed based on a difference between the estimated temperature of the battery system and a target temperature for the battery system.

9. The proactive temperature management system of claim 6, wherein the fluid is a liquid coolant and the flow control device includes one or more pumps configured to control the flow of the liquid coolant therethrough.

10. The proactive temperature management system of claim 6, wherein the fluid is an air and the flow control device includes one or more fans configured to control the flow of the air therethrough.

11. A proactive temperature management method for a battery system of an electrified vehicle, the proactive temperature management method comprising:
providing a set of sensors configured to measure (i) a current flowing through the battery system and (ii) an inlet temperature and an outlet temperature of a fluid in a cooling system at respective inlet and output points of a coolant path of the cooling system relative to the battery system;
estimating, by a control system of the electrified vehicle, a temperature of the battery system based on the measured inlet and outlet temperatures;
detecting, by the control system, a proactive temperature management condition when the measured current exceeds one or more current thresholds;
in response to detecting the proactive temperature management condition, controlling, by the control system, the cooling system to increase a flow of the fluid therethrough to proactively cool the battery system to a target temperature;
after the proactive temperature management condition has expired, estimating, by the control system, a state of charge (SOC) of the battery system based on the estimated temperature of the battery system; and
controlling, by the control system, the battery system based on the estimated SOC of the battery system.

12. The proactive temperature management method of claim 11, wherein the proactive cooling of the battery system increases an accuracy of the estimated SOC of the battery system and thereby improves discharge performance of the battery system.

13. The proactive temperature management method of claim 11, wherein the control system is configured to detect the proactive temperature management condition when (i) a magnitude of the measured current exceeds a calibratable current magnitude threshold and (ii) a rate of change of the measured current exceeds a calibratable current rate of change threshold.

14. The proactive temperature management method of claim 11, wherein the proactive temperature management condition expires when a difference between the measured outlet temperature and the target temperature for the battery system falls below one or more respective thresholds.

15. The proactive temperature management method of claim 14, wherein the proactive temperature management condition expires when (i) an absolute value of the difference between the measured outlet temperature and the target temperature is less than a calibratable difference threshold and (ii) a rate of change of the difference between the measured outlet temperature and the target temperature is less than a calibratable temperature rate of change threshold.

16. The proactive temperature management method of claim 11, wherein the control of the cooling system to increase the flow of the fluid therethrough comprises controlling a flow control device of the cooling system.

17. The proactive temperature management method of claim 16, wherein the controlling of the flow control device of the cooling system includes selecting and commanding one of at least two different flow rates for the flow control device, wherein each of the at least two different flow rates is greater than zero.

18. The proactive temperature management method of claim 17, wherein the selecting of the one of the at least two different flow rates is performed based on a difference between the estimated temperature of the battery system and a target temperature for the battery system.

19. The proactive temperature management method of claim 16, wherein the fluid is a liquid coolant and the flow control device includes one or more pumps configured to control the flow of the liquid coolant therethrough.

20. The proactive temperature management method of claim 16, wherein the fluid is an air and the flow control device includes one or more fans configured to control the flow of the air therethrough.
